(19) United States
(12) Patent Application Publication
(10) Pub. No.: US 2007/0228369 A1
(43) Pub. Date: Oct. 4, 2007

(54) SUBSTRATUM WITH CONDUCTIVE FILM AND PROCESS FOR PRODUCING THE SAME

(75) Inventors: Susumu Suzuki, Yokohama-shi (JP); Akira Mitsui, Yokohama-shi (JP); Kazuya Yaoita, Yokohama-shi (JP); Takuji Oyama, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: ASAHI GLASS CO., LTD., Tokyo (JP)

(21) Appl. No.: 11/759,634

(22) Filed: Jun. 7, 2007

Related U.S. Application Data
(63) Continuation of application No. PCT/JP05/20191, filed on Nov. 2, 1995.

(30) Foreign Application Priority Data
Dec. 8, 2004 (JP) 2004-355265
May 10, 2005 (JP) 2005-137326

(51) Int. Cl. H01L 29/08

(52) U.S. Cl. 257/40

(57) ABSTRACT

A process for producing a substratum with conductive film excellent in surface smoothness, is provided which does not require complicated steps after film-forming such as heating treatment, polishing of film surface or oxygen plasma treatment after film-forming.

The present invention provides a substratum with conductive film comprising a substratum and a conductive film containing tin-doped indium oxide as the main component, wherein a foundation film containing zirconium oxide doped with yttrium oxide as the main component is formed on the substratum side of the conductive film, and wherein the content of yttrium oxide in the foundation film is preferably from 0.1 to 50 mol % based on the total amount of Y₂O₃ and ZrO₂.

### TECHNICAL FIELD

The present invention relates to a substratum with conductive film to be mainly employed for an organic EL, and to its production process.

### BACKGROUND ART

A conductive film (hereinafter, it is also referred to as ITO film) containing tin-doped indium oxide as the main component, is employed as a transparent conductive film for electrodes of display devices such as LCDs (liquid crystal display) or organic EL elements (electroluminescence elements) or solar cells. An ITO film has characteristics that it is excellent in conductivity, it has high visible light transmittance and high durability against chemicals but it is soluble to a type of acid, and thus, it is easily patterned.

From the viewpoint of conductivity or durability against chemicals, the ITO film is preferably crystallized. However, a crystallized film tends to have irregularities formed on its surface. In a case of employing an ITO film for e.g. an electrode for an organic EL element, large irregularities on a surface of the ITO film causes problems such as leak current or dark spot.

It is proposed to form an ITO film under a relatively low temperature of from 10 to 150° C. and subsequently apply the ITO film a heat process of from 100 to 450° C. to make the ITO film have a crystal orientation of (111) in order to suppress leak current or dark spot of an organic EL element (for example, refer to Patent Document 1). However, a heat process after film-forming makes the production process complicated, which is not preferred in terms of productivity. Further it has been attempted to reduce surface irregularities of ITO films by polishing or applying acid treatment to ITO film surfaces, but these methods also makes production process complicated, which lowers productivity.

Further, a method of smoothening an ITO surface by forming a zirconium oxide film as a foundation film between the ITO film and a substrate (for example, refer to Patent Document 2) and a method of forming a zirconium oxide film as a foundation film between the ITO film and a substrate and reverse-sputtering the ITO surface in a sputtering gas containing oxygen gas (for example, refer to Patent Document 3). However, in the case of ITO film formed on such a foundation film of only the zirconium oxide film, surface flatness becomes insufficient. Further, in the method of reverse sputtering an ITO film surface in a sputtering gas containing oxygen gas, a formed film has to be put in a vacuum apparatus for reverse sputtering, which increases equipment cost.

Patent Document 1: JP-A-11-87068

Patent Document 2: JP-A-2002-170430

Patent Document 3: JP-A-2003-335552

### DISCLOSURE OF THE INVENTION

### Problems to be Solved by the Invention

It is an object of the present invention to provide a substratum with conductive film not requiring complicated process steps such as heating treatment, polishing of film surface or oxygen plasma treatment after forming the film, and excellent in surface smoothness. Further, the present invention provides a process for producing a substratum with conductive film not requiring complicated process steps such as heating treatment, polishing of film surface or oxygen plasma treatment after forming the film and excellent in surface smoothness.

### Means for Solving the Problems

The present invention provides a substratum with conductive film, comprising a substratum and a conductive film containing a tin-doped indium oxide as the main component formed on the substratum, wherein a foundation film containing as the main component zirconium oxide doped with yttrium oxide is formed on a substratum side of the conductive film. In the present invention, it is preferred that the content of yttrium oxide in the foundation film is from 0.1 to 55 mol % based on total amount of Y₂O₃ and ZrO₂. In the present invention, it is also preferred that the average roughness Rₐ of a surface of the conductive film containing tin-doped indium oxide as the main component, is at most 1.8 nm.

Further, the present invention provides a process for producing a substratum with conductive film, comprising a step of forming on a substratum a foundation film containing zirconium oxide as the main component, a step of forming on the foundation film a conductive film containing tin-doped indium oxide as the main component, and a step of ion-etching a surface of the conductive film using as an etching gas an ionized gas containing argon or oxygen as the main component. Further, the present invention provides a process for producing a substratum with conductive film, comprising a step of forming on a substratum a foundation film containing zirconium oxide as the main component, a step of forming on the foundation film a conductive film containing tin-doped indium oxide as the main component, a step of ion-etching a surface of the conductive film using as an etching gas an ionized gas containing argon or oxygen as the main component, and a step of further forming on the surface of the etched conductive film a conductive film containing tin-doped indium oxide as the main component.

Further, the present invention provides a process for producing a substratum with conductive film, comprising a step of forming on a substratum a foundation film containing zirconium oxide as the main component, a step of forming on the foundation film a conductive film containing tin-doped indium oxide as the main component, a step of ion-etching a surface of the conductive film using as an etching gas an ionized gas containing argon or oxygen as the main component, a step of further forming on the surface of the etched conductive film a conductive film containing tin-doped indium oxide as the main component and further ion-etching a surface of the conductive film using as an etching gas an ionized gas containing argon or oxygen as the main component. In the present invention, it is preferred that the foundation film contains zirconium oxide doped with yttrium oxide as the main component, and the content of yttrium oxide in the foundation layer is from 1 to 50 mol % based on the total amount of Y₂O₃ and ZrO₂. In the present invention, it is also preferred that the content of argon in the etching gas is from 1 to 100 vol %.

In the present invention the average surface roughness of ITO film surface means the average surface roughness of a surface of a substrate with conductive film.

### Effects of the Invention

According to the present invention it is possible to obtain a substrate with conductive film having little surface irregularities and excellent flatness without requiring complicated production steps such as heating treatment, polishing of ITO film surface, oxygen plasma treatment or acid treatment after forming the film. The substrate with conductive film of the present invention has excellent flatness and transparency, and thus, is suitable for electrodes for organic EL elements, and in the substrate, leak current and dark spot are suppressed. Further, the substrate is excellent in conductivity.

### BRIEF DESCRIPTION OF THE DRAWINGS

FIG. 1: FIG. 1 is a schematic cross-sectional view showing an embodiment of a substratum with conductive film of the present invention.

### EXPLANATION OF NUMERALS

1: substrate with conductive film

10: substratum

20: foundation film

30: conductive film

### BEST MODE FOR CARRYING OUT THE INVENTION

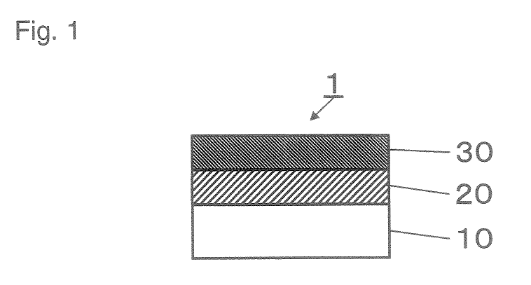

The present invention provides, as shown in FIG. 1, a substratum 1 with conductive film comprising a substratum 10 and a conductive film 30 containing tin-doped indium as the main component formed on the substratum 10, characterized by further comprising a foundation layer 20 containing zirconium oxide doped with yttrium oxide as the main component is formed on the substrate side of the conductive film 30.

The substratum of the present invention is not particularly limited, and it may be an inorganic substratum such as a glass substrate, or an organic substratum such as a plastic substrate. Particularly, the substratum is preferably a glass substrate for the reason that it is possible to raise substrate temperature at a time of film-forming by a sputtering method. The glass substrate may be an alkali-containing glass substrate such as soda lime silicate glass substrate or a non-alkali glass substrate (containing substantially no alkali component) such as a borosilicate glass substrate. In a case of glass substrate, the thickness of the glass substrate is preferably from 0.3 to 3 mm for the reason of transparency. The average surface roughness Rₐ of the glass substrate is from 0.1 to 10 nm, preferably from 0.1 to 5 nm, particularly preferably from 0.1 to 1 nm. In the present invention, an average surface roughness Rₐ is measured by a roughness tester (manufactured by Seiko Instruments: SPA400) and an AFM (manufactured by Seiko Instruments: SPI3800N) under the condition that the scanning area is 3 μm×3 μm and the cut-off value is 1 μm.

When an alkali-containing glass substrate is employed as the substratum, in order to prevent alkali ions contained in the glass substrate from being diffused into the ITO film to affect specific resistance of the ITO film, it is preferred to form between the substratum 1 and the ITO film e.g. a silicon dioxide (SiO₂) film as an alkali-barrier layer. The average surface roughness Rₐ of a surface of the alkali-barrier layer is from 0.1 to 10 nm, preferably from 0.1 to 5 nm, particularly preferably from 0.1 to 1 nm.

The method for forming the alkali-barrier layer is not particularly limited, and the method may, for example, be a thermal decomposition method (a method of applying a raw material solution and heating it to form a film), a CVD method, a sputtering method, a vapor deposition method or an ion plating method. For example, in a case of SiO₂ film, the film-forming method may be an RF (high frequency) sputtering method employing a SiO₂ target or an RF or a DC (direct current) sputtering method employing a Si target, are mentioned. In a case of employing a Si target, the sputtering gas is preferably an Ar/O₂ mixed gas and the gas ratio between Ar and O₂ is preferably determined so that the alkali-barrier layer does not absorb visible light. The film thickness of the SiO₂ film is preferably at least 10 nm in terms of alkali-barrier property, and preferably at most 500 nm in terms of cost. Here, the film thickness means geometric film thickness, and this definition applies hereinafter.

The foundation film of the present invention is a film containing zirconium oxide as the main component. The foundation film preferably contains at least 85 mol % of zirconium oxide. The foundation film preferably contains yttrium oxide Y₂O₃) as an additive. When Y₂O₃ is mixed in ZrO₂, flatness of ITO film surface before applying ion-etching is improved as compared with a foundation film of pure ZrO₂ film (a ZrO₂ film not containing yttrium oxide). The reason for this effect is not clear, but the inventors assume it is because a surface of the Y₂_{O}₃-doped ZrO₂ film is more flat than that of pure ZrO₂, or because an ITO film is epitaxially grown on the ZrO₂ film. The content of Y₂O₃ is from 1 to 50 mol %, preferably from 1 to 20 mol %, particularly preferably from 1 to 10 mol % based on total amount of ZrO₂ and Y₂O₃. If the content is less than 1 mol %, flattening effect of ITO film is not enough, and if it exceeds 50 mol %, the film becomes a film containing Y₂O₃ as the main component and flattening effect decreases. Further, the foundation film may contain e.g. Hf, Fe, Cr, Ca or Si as impurities, but the total amount of impurities is preferably at most 5 at %, particularly preferably at most 1 at % based on total amount of Zr and impurity elements.

The film thickness of the foundation film is preferably from 1 to 15 nm, particularly preferably from 3 to 12 nm. When a foundation film of this film thickness is present, it becomes possible to make average surface roughness Rₐ 3.0 nm or smaller before applying ion etching treatment to a surface of a substratum with conductive film obtained. The foundation film of the present invention can influence crystal growth of an ITO film formed thereon to change crystal orientation of the ITO film, which contributes to improve surface flatness of the substratum with conductive film obtained. If the film thickness of the foundation film is less than 1 nm, the effect of foundation film reducing average surface roughness of ITO film surface, is hardly obtained. If the film thickness of the foundation film exceeds 15 nm, such a film thickness is not preferred in terms of film-forming cost of the foundation film. Here, the film thickness of the foundation film described above means an average film thickness, and this definition is also applied to a case where the film is not a continuous film.

A method for forming the foundation film is not particularly limited, and the method may be a thermal decomposition method, a CVD method, a sputtering method, a vapor deposition method or an ion inflating method. For example, the foundation film is formed by an RF sputtering method in an Ar or Ar/O₂ atmosphere using a Y₂O₃-doped ZrO₂ target. In a case of ZrO₂ film, the film is formed by a reactive RF or a reactive DC sputtering method in an Ar/O₂ atmosphere using a Zr target. Y₂O₃-doped ZrO₂ is known as a stabilized zirconia, in which phase transition of crystal structure due to temperature change is minimized as compared with ZrO₂, whereby the material has high thermal stability and it is preferred in the point that it can prevent heat-induced breakage of a target. Further, when a SiO₂ film being an alkali-barrier layer is formed by an RF sputtering method using a SiO₂ target, the SiO₂ film as an alkali-barrier layer and a Y₂O₃-doped ZrO₂ film can be formed in the same atmosphere.

An ITO film is a film comprising In₂O₃ and SnO₂, and total content of In₂O₃ and SnO₂ is preferably at least 90 at %. Further, in terms of the composition, the content of SnO₂ is preferably from 1 to 20 mass % based on the total amount. (In₂O₃+SnO₂) of In₂O₃ and SnO₂. The film thickness of the ITO film is from 100 to 500 nm, is preferably from 100 to 300 nm, particularly preferably from 100 to 200 nm from the viewpoints of e.g. resistivity and transparency. In a case where the ITO film is employed for an organic EL element, by making the film have good crystallinity, the film preferably has a specific resistance of at most 4×10⁻⁴ Ω·cm and a sheet resistance of at most 20 Ω/□. Further, in a case where the ITO film is employed as a transparent electrode, a substratum with ITO film preferably has a visible light transmittance according to JIS-R3106 (1998) of at least 85%.

The method for forming the ITO film is not particularly limited, and it may for example, be a thermal decomposition method, a CVD method, a sputtering method, a vapor deposition method or an ion inplating method. Considering stability of film thickness or possibility of forming a film of large area, film-forming by a sputtering method is preferred. For example, a method of forming the ITO film by an RF or a DC sputtering method employing an ITO target, is mentioned. It is preferred that Ar/O₂ mixed gas is used as a sputtering gas and adjust flow rate ratio of Ar/O₂ so as to minimize the specific resistance of ITO.

The film-forming temperature at the time of sputtering is from 100 to 500° C., preferably from 200 to 500° C., particularly preferably from 200 to 400° C. or from 200 to 350° C. If the film-forming temperature is lower than 100° C., ITO tends to be amorphous and durability of the film against chemicals tends to be low. If the film-forming temperature is higher than 500° C., crystallization is promoted and irregularities of film surface tend to be large. In the present invention when the film-forming is carried out at the above-mentioned film-forming temperatures a film excellent in flatness which has high transparency and low specific resistance, can be obtained, such being preferred.

The average surface roughness Rₐ of the ITO film is at most 1.3 nm, preferably at most 1.5 nm, particularly preferably at most 1 nm or at most 0.8 nm. By making the surface roughness small, leak current or dark spot can be suppressed when the ITO film is used as an electrode for an organic EL element, such being preferred.

When an ion etching treatment is applied to a conductive film, surface irregularities are etched by accelerated ions to be averaged, and thus, the average surface roughness Rₐ is further decreased. When ion etching treatments are carried out under the same conditions, final average surface roughness Rₐ of a foundation film of Y₂O₃-doped ZrO₂ after the treatment, becomes further smaller than that of a foundation film of a pure ZrO₂. Accordingly, when a specific target average surface roughness Pa is set, Y₂O₃-doped ZrO₂ foundation film can reduce ion etching time to reach a specific target average surface roughness Rₐ. Further, the foundation film can achieve high flatness.

In terms of components of etching gas to be used for the above-mentioned ion etching treatment, a gas containing argon or oxygen as the main component is preferred for the reasons that argon gas has large etching effect and is low cost, and further, oxygen gas hardly influences physical properties of ITO being an oxide, and it is possible to carry out film-forming by sputtering and ion etching in the same chamber. Total content of argon and oxygen in the etching gas is preferably at least 90 vol %. Particularly, since discharge of a linear ion source tends to be unstable if the content of oxygen is high, the content of argon in the etching gas is preferably from 1 to 100 vol %. Here, by carrying out an ion etching treatment, the film is cut off by 6 to 9 nm. Accordingly, in a case of forming double layer or multilayer conductive films as described later, it is preferred to consider total film thickness considering the thicknesses of the films to be cut off. Further, an ion etching amount can be estimated by a product obtained by multiplying etching power and etching time, namely by accumulated electric power. The accumulated electric power is preferably large in terms of a purpose of reducing average surface roughness of a surface, but the accumulated electric power is preferably at least 0.001 W·h per a unit etching area (cm²) in terms of exhibiting an effect of reducing irregularities.

After the above-mentioned ion etching treatment, an additional conductive film containing a tin-doped indium oxide as the main component may be formed on a surface of the etched conductive film. Lamination of two layers of such conductive films, forms a single film in terms of composition, and enables to obtain a conductive film having better flatness. The reason why film-forming after etching causes good flatness, is unclear but the inventors assume that the reason relates to orientation of the film. Here, the method for forming the conductive film is same as the above-mentioned method. Here, the film thickness of total conductive film is preferably from 100 to 500 nm as described above even in a case of laminating two layers of films.

Further, a surface of the conductive film formed may be subjected to an ion etching using ions of a gas containing argon or oxygen as the main component as an etching gas. Namely, forming of the conductive film and the ion etching may be each repeated twice. By this ion etching treatment, it becomes possible to obtain a conductive film having still better flatness. Here, the method of ion etching is same as the above-mentioned method.

Further, after the forming of foundation film, forming of conductive film and ion etching treatment may be repeated. By such a method, multilayer films are formed as if they constitute a single film, which enables to obtain a conductive film having still better flatness. In this case, the multilayer conductive films are preferably the same or substantially the same conductive films containing tin-doped indium oxide as the main component. Here, even in the case of forming multilayer conductive films, the film thickness of total conductive films is preferably from 100 to 500 nm as described above.

The substratum with conductive film of the present invention is suitable as an electrode for display devices such as LCDs, inorganic EL elements, or organic EL elements, or an electrode for solar cells. In particular, an organic EL element comprising a hole injection electrode, an electron injection electrode and an organic emission layer between these electrodes, wherein the substratum with conductive film of the present invention is employed as the hole injection electrode, is one of suitable examples employing the substratum with conductive film of the present invention.

### EXAMPLES

Examples 1 to 4 and 7 to 10 (Examples of the present invention) and Examples 5 and 6 (Comparative Examples) are shown below. In Examples 1 to 10, average surface roughnesses Rₐ were measured by a roughness meter (manufactured by Seiko Instruments: model SPA400) and an AFM (manufactured by Seiko Instrument: model SPI3800N). Scanning area was 3 μm×3 μm and cut off value was set of 1 μm. Specific resistance were measured by Loresta MCPT-400 manufactured by Mitsubishi Yuka (Dia Instruments) Loresta MCPT-400. Visible light transmittance was measured by a simple transmittance meter (manufactured by Asahi-Spectra: model 304).

### Example 1

A cleaned soda lime silicate glass substrate (average surface roughness Rₐ was 0.5 nm, thickness was 0.7 mm, visible light transmittance was 85% ) was set in a sputtering apparatus, and heated to a substrate temperature of 250° C. On the substrate, a SiO₂ film was formed as an alkali-barrier layer by an RF sputtering method using a SiO₂ target. The flow rate ratio of Ar/O₂ was 40/10, the pressure was 3 mTorr (0.4 Pa in SI unit) and the sputtering powder density was 2.74 W/cm². The SiO₂ film was formed to have film thickness of 20 nm. The composition of the film formed was the same as that of the target.

Then, on the SiO₂ film, a Y₂O₃-doped ZrO₂ film was formed as a foundation film by an RF sputtering method. The material of sputtering target used consisted of 3 mol % of Y₂O₃ (content of Y₂O₃ was 3 mol % based on total amount of Y₂O₃ and ZrO₂ and 97 mol % of ZrO₂. The flow rate ratio of ArO₂ was 40/10, the pressure was 3 mTorr and the sputtering power density was 2.74 W/cm². The film thickness of the Y₂O₃-doped ZrO₂ film was 9 nm. The composition of the film formed was the same as that of the target.

Subsequently on the foundation film, an ITO film was formed as a conductive film by a DC sputtering method. The material of the target used consisted of 10 mass % of SnO₂ (the content of SnO₂ was 10 mass % based on total amount of In₂O₃ and SnO₂) and 90 mass % of In₂O₃. The flow rate ratio of ArO₂ was 99.5/0.5, the pressure was 5 mTorr and the sputtering power density was 1.64 W/cm². The ITO film was formed to have a film thickness of 160 nm. The composition of the film formed was the same as that of the target.

The average surface roughness Rₐ of the ITO film obtained was measured. Rₐ was 1.2 nm.

### Example 2

A substrate with ITO film obtained in Example 1 was subjected to Ar ion etching using a linear ion source (manufactured by Advanced Energy: model LIS-38, irradiation area was 5 cm×38 cm). 30 sccm of Ar gas was flown in the linear ion source, and Ar gas was flown separately in a vacuum chamber to which the linear ion source was attached so that the pressure of entire system became 1.9 mTorr. The acceleration voltage of the linear ion source was set to 2 kV and the ion current was set to 210 mA. Under these conditions, the ITO film was irradiated with argon ion beam for 4 seconds (accumulated power was 0.0024 W·h).

The average surface roughness Rₐ of the ITO film after the ion etching treatment was measured, Rₐ was 0.9 nm.

### Example 3

The substrate with ITO film obtained in Example 1 was subjected to Ar ion etching by using a linear ion source (manufactured by Applied Ion Beam: model IS336, irradiation area was 5 cm×10 cm). 3 sccm of Ar gas was flown in the linear ion source so that the pressure in the entire chamber became 0.2 mTorr. The acceleration voltage of the linear ion source was set to 3 kV and the ion current was set to 45 mA. Under these conditions, the ITO film was Irradiated with argon ion beam for about 40 seconds (accumulated power was 0.005 W·h).

The average surface roughness Rₐ Of the ITO film after the ion etching treatment was measured. Rₐ was 0.6 nm.

### Example 4

A substrate with ITO film was obtained in the same manner as Example 1 except that a ZrO₂ film was formed instead of the Y₂O₃-doped ZrO₂ film of Example 1.

The ZrO₂ film was formed by an RF sputtering method. The material of the sputtering target used was Zr. The flow rate ratio of Ar/O₂ was 40/10, the pressure was 3 mTorr and the sputtering power density was set to 2.74 W/cm². The ZrO₂ film was formed to have a film thickness of 9 nm. The composition of the film formed was the same as that of the target

The ITO film obtained was subjected to Ar ion etching in the same method as that of Example 3, and the average surface roughness Rₐ of the ITO film after the ion etching treatment was measured. Rₐ was 0.8 nm.

### Example 5

### Comparative Example

A substrate with ITO film was obtained in the same manner as Example 1 except that a ZrO₂ film was formed instead of the Y₂O₃-doped ZrO₂ film of Example 1.

The average surface roughness Rₐ of the ITO film obtained was measured. Rₐ was 1.9 nm.

### Example 6

### Comparative Example

A substrate with ITO film was obtained in the same manner as Example 1 except that the Y₂O₃-doped ZrO₂ film of Example 1 was not formed.

The average surface roughness Rₐ of the ITO film obtained was measured. Rₐ was 2.4 nm.

### Example 7

In the same manner as Example 1, an SiO₂ film and a Y₂O₃-doped ZrO₂ film were formed on a cleaned soda lime silicate glass substrate by an RF sputtering method.

Subsequently, as a conductive film, an ITO film was formed on the foundation film by an RF sputtering method. The material of the target used consisted of 10 mass % of SnO₂ (the content of SnO₂ was 10 mass % based on the total amount of In₂O₃ and SnO₂) and 90 mass % of In₂O₃. The flow rate ratio of Ar/O₂ was 99.5/0.5 the pressure was 5 mTorr and the sputtering power density was set to 1.64 W/cm² The substrate temperature was set to 380° C. The ITO film was formed to have a film thickness of 150 nm. The composition of the film formed was the same as that of the target.

The average surface roughness Rₐ of the ITO film obtained was measured. Rₐ was 1.5 nm.

### Example 8

A substrate with ITO film was obtained in the same manner was Example 7 except that the film thickness of the ITO film of Example 7 was changed from 150 nm to 100 nm.

The substrate with ITO film was subjected to Ar ion etching under the same conditions as those of Example 2. Further, on the substrate with ITO film obtained, another ITO film was formed under the same conditions as those of Example 7, so that the film thickness of whole ITO film became 150 nm.

The average surface roughness Rₐ of the ITO film obtained was measured. Rₐ was 1.4 nm.

### Example 9

A substrate with ITO film was obtained in the same manner as Example 7 except that the film thickness of the ITO film of Example 7 was changed from 150 to 100 nm.

The substrate with ITO film was subjected to Ar ion etching under the same conditions as those of Example 2. Further, on the substrate with ITO film obtained, another ITO film was formed under the same conditions as those of Example 7, and subsequently, the substrate with ITO film was subjected to Ar ion etching under the same conditions as those of Example 2, so that the film thickness of whole ITO film became 150 nm.

The average surface roughness Rₐ of the ITO film obtained was measured. Rₐ was 0.9 nm.

### Example 10

A substrate with ITO film was obtained in the same manner as Example 7 except that the film thickness of the ITO film of Example 7 was changed from 150 nm to 100 nm.

The substrate with ITO film was subjected to Ar ion etching under the same conditions as those of Example 3. Further, on the substrate with ITO film, another ITO film was formed under the same conditions as those of Example 7, and subsequently the substrate with ITO film was subjected to Ar ion etching so that the film thickness of whole ITO film became 150 nm.

The average surface roughness Rₐ of the ITO film obtained was measured. Rₐ was 0.4 nm.

Here, the visible light transmittance according to JIS-R3106 (year 1998) of the substrate with ITO film obtained in each of Examples 1 to 9, was at least 85% and the resistance was good enough to be usable for organic EL elements.

The average surface roughnesses of the ITO films obtained are shown in Table 1 as well as the types of foundation films and conductive films.

TABLE 1

| | | | | Average |
|---|---|---|---|---|
| | Foundation | | | surface |
| | film | Conductive film | | roughness |
| Example | Type | Type | Film thickness | (nm) |
| 1 | Y₂O₃-doped | ITO | 160 | 1.2 |
| | ZrO₂ | | | |
| 2 | Y₂O₃-doped | ITO/etching | 160 | 0.9 |
| | ZrO₂ | | | |
| 3 | Y₂O₃-doped | ITO/etching | 160 | 0.6 |
| | ZrO₂ | | | |
| 4 | ZrO₂ | ITO/etching | 160 | 0.8 |
| 5 | ZrO₂ | ITO | 160 | 1.9 |
| 6 | None | ITO | 160 | 2.4 |
| 7 | Y₂O₃-doped | ITO | 150 | 1.5 |
| | ZrO₂ | | | |
| 8 | Y₂O₃-doped | ITO/etching/ | 150 | 1.4 |
| | ZrO₂ | ITO | | |
| 9 | Y₂O₃-doped | ITO/etching/ | 150 | 0.9 |
| | ZrO₂ | ITO/etching | | |
| 10 | Y₂O₃-doped | ITO/etching/ | 150 | 0.4 |
| | ZrO₂ | ITO/etching | | |

### INDUSTRIAL APPLICABILITY

The substrate with conductive film of the present invention is excellent in surface smoothness and useful particularly for organic EL elements.

The entire disclosures of Japanese Patent Application No. 2004-355265 filed on Dec. 8, 2004 and Japanese Patent Application No. 2005-137326 filed on May 10, 2005 including specifications, claims, drawings and summaries are incorporated herein by reference in their entireties.

What is claimed is:

1. A substratum with conductive film, comprising a substratum and a conductive film containing a tin-doped indium oxide as the main component formed on the substratum, wherein a foundation film containing as the main component zirconium oxide doped with yttrium oxide is formed on a substratum side of the conductive film.

2. The substratum with conductive film according to claim 1, wherein the content of yttrium oxide in the foundation film is from 0.1 to 50 mol % based on total amount of Y₂O₃ and ZrO₂.

3. The substratum with conductive film according to claim 1, wherein the average surface roughness Rₐ of a surface of the conductive film is at most 1.8 nm.

4. The substratum with conductive film according to claim 1, which further comprises an alkali-barrier layer between the substrate and the foundation film.

5. The substratum with conductive film according to claim 1, wherein the thickness of the foundation film is from 1 to 15 nm.

6. The substratum with conductive film according to claim 1, wherein the thickness of the conductive film is from 100 to 500 nm.

7. The substratum with conductive film according to claim 1, wherein the specific resistance of the conductive film is at most 4×10⁻⁴ Ω·cm.

8. The substratum with conductive film according to claim 1, wherein the visible light transmittance of the substratum with conductive film is at least 85%.

9. A process for producing a substratum with conductive film, comprising a step of forming on a substratum a foundation film containing zirconium oxide as the main component, a step of forming on the foundation film a conductive film containing tin-doped indium oxide as the main component, and a step of ion-etching a surface of the conductive film using as an etching gas an ionized gas containing argon or oxygen as the main component.

10. A process for producing a substratum with conductive film, comprising a step of forming on a substratum a foundation layer containing zirconium oxide as the main component, a step of forming on the foundation film a conductive film containing tin-doped indium oxide as the main component, a step of ion-etching a surface of the conductive film using as an etching gas an ionized gas containing argon or oxygen as the main component, and a step of forming on the surface of the etched conductive film a single or a plurality of conductive films containing tin-doped indium oxide as the main component by repeating the forming of a conductive film and the ion-etching of a surface of the conductive film.

11. A process for producing a substratum with conductive film, comprising a step of forming on a substratum a foundation film containing zirconium oxide as the main component, a step of forming or the foundation film a conductive film containing tin-doped indium oxide as the main component, a step of ion-etching a surface of the conductive film using as an etching gas an ionized gas containing argon or oxygen as the main component, a step of forming on the surface of the etched conductive film a single or a plurality of conductive films containing tin-doped indium oxide as the main component by repeating the forming of a conductive film, and the ion-etching of a surface of the conductive film and a step of ion-etching a surface of the formed uppermost conductive film using as an etching gas an ionized gas containing argon or oxygen as the main component.

12. The process for producing a substratum with conductive film according to claim 9, wherein the foundation film is a foundation film containing zirconium oxide doped with yttrium oxide as the main component, and the content of yttrium oxide in the foundation layer is from 0.1 to 50 mol % based on the total amount of Y₂O₃ and ZrO₂.

13. The process for producing a substratum with conductive film according to claim 9, wherein the content of argon in the etching gas is from 1 to 100 vol %.

14. A substratum with conductive film obtained by the process for producing a substratum with conductive film according to claim 9.

15. An organic EL element employing as a hole-injection electrode the substratum with conducive film as defined In claim 1.
